(19) United States
(12) Patent Application Publication
(10) Pub. No.: US 2025/0028866 A1
(43) Pub. Date: Jan. 23, 2025

(54) PROMPTABLE FOOD MANUFACTURING

(71) Applicant: Aicadium Holdings Pte. Ltd., Singapore (SG)

(72) Inventors: Dimitry FISHER, San Diego, CA (US); Joshua JACOBSON, Ann Arbor, MI (US)

(21) Appl. No.: 18/778,845

(22) Filed: Jul. 19, 2024

Related U.S. Application Data
(60) Provisional application No. 63/528,317, filed on Jul. 21, 2023.

(51) Int. Cl. G06F 30/10

(52) U.S. Cl. CPC G06F 30/10

(57) ABSTRACT

Certain aspects of the disclosure pertain to promptable food manufacturing. A prompt can be received, and at least one two-dimensional image and a three-dimensional model can be produced using generative artificial intelligence based on the prompt. The two-dimensional image and three-dimensional model can be refined through iterative user feedback. The three-dimensional model can be validated against physical, technical, and logistic constraints utilizing simulation and machine learning models. After validation, instructions can be generated based on the three-dimensional model, targeting one or more manufacturing devices. The instructions can then be transmitted to one or more manufacturing devices to produce a food item. The produced food item can subsequently be scanned and compared to the three-dimensional model. Differences can be determined and utilized to update the instructions generated.

### CROSS-REFERENCE TO RELATED APPLICATIONS

This application claims the benefit of and priority to U.S. Provisional Patent Application No. 63/528,317, filed Jul. 21, 2023, and entitled “Promptable 3D Food Manufacturing,” the entirety of which is hereby incorporated by reference.

### BACKGROUND

### Field

Aspects of the subject disclosure relate to machine learning and automated manufacturing and production systems.

### Description of Related Art

Manufacturing processes often rely on manual design, prototyping, and production workflows, which can be time-consuming and error-prone. Moreover, conventional manufacturing processes are limited in their ability to produce custom products and require specialized machinery. Advances in areas such as computer numeric control (CNC) machining and additive manufacturing (e.g., 3D printing) have provided automated systems that can generate custom products.

### SUMMARY

One aspect provides a method, comprising receiving a prompt from a user, the prompt is text describing a food item to be produced, generating a two-dimensional image of the food item by a first generative artificial intelligence model based on the prompt, generating a three-dimensional model of the food item by a second generative artificial intelligence model based on the two-dimensional image, generating one or more instructions for producing the food item based on the three-dimensional model, and triggering production of the food item according to the one or more instructions.

Another aspect provides a method, comprising scanning a food item produced by one or more additive or subtractive manufacturing devices based on one or more instructions automatically generated from a three-dimensional model produced in response to a prompt, determining a difference between the food item and the three-dimensional model, and transmitting the difference to a food generation system to trigger design modification.

Other aspects provide processing systems configured to perform the aforementioned methods as well as those described herein; non-transitory, computer-readable media comprising instructions that, when executed by a processor of a processing system, cause the processing system to perform the aforementioned methods as well as those described herein; a computer program product embodied on a computer-readable storage medium comprising code for performing the aforementioned methods as well as those further described herein; and a processing system comprising means for performing the methods above as well as those further described herein.

The following description and the related drawings set forth in detail certain illustrative features of one or more aspects.

### DESCRIPTION OF THE DRAWINGS

The appended figures depict certain aspects and are therefore not to be considered limiting of the scope of this disclosure.

FIG. 1 depicts an example implementation of promptable food manufacturing.

FIG. 2 is a block diagram of an example implementation of a food generation system.

FIG. 3 is a block diagram of an example implementation of an instruction component.

FIG. 4 is a flow chart diagram of an example food generation method.

FIG. 5 is a flow chart diagram of an example instruction generation method.

FIG. 6 is a flow chart diagram of an example food analysis method.

FIG. 7 depicts an example processing system with which aspects of the subject disclosure can be performed.

To facilitate understanding, identical reference numerals have been used, where possible, to designate identical elements that are common to the drawings. It is contemplated that elements and features of one embodiment may be beneficially incorporated in other embodiments without further recitation.

### DETAILED DESCRIPTION

Aspects of the subject disclosure provide apparatuses, methods, processing systems, and computer-readable mediums for designing and manufacturing novel goods and services, such as custom food recipes or designs, using generative AI models. In particular, aspects described herein relate to methods for designing and producing such goods and providing such services, as well as example hardware implementations and principles of training and operation.

Subtractive and additive manufacturing enable automated generation of customized products and prototypes. Subtractive manufacturing uses computer-controlled tools to precisely cut, shape, and carve materials into desired products. Computer numeric control (CNC) manufacturing is representative of a subtractive manufacturing process, which allows for high-precision manufacturing but can be limited in the complexity of products produced. Additive manufacturing, by contrast, builds up objects layer-by-layer using materials, including food-grade substances. Three-dimensional (3D) printing is a form of additive manufacturing that provides more flexibility in creating complex geometries and customized designs. However, custom manufacturing utilizing subtractive or additive manufacturing requires specialized skills and knowledge to operate. Further, subtractive and additive manufacturing are often associated with high cost, scale and speed limitations, and material constraints. These factors hinder the adoption of such advanced manufacturing techniques for custom products and lead to continued reliance on traditional manufacturing methods.

Aspects of the subject disclosure provide technical solutions to at least the aforementioned problems and improve automated manufacturing overall by streamlining product development and ensuring the quality of a final product. In particular, generative artificial intelligence and human-in-the-loop feedback can be exploited to enable faster custom manufacturing and prototyping without requiring specialized skills or knowledge. A user prompt can specify a custom product or prototype. From the prompt, one or more two-dimensional (2D) images can be produced automatically with generative artificial intelligence. A user can review the one or more 2D images and adjust the prompt if needed to refine the images. Subsequently, a 3D model can be generated based on the one or more 2D images. User feedback regarding the model can be obtained to refine the 3D model, for example, by altering the prompt. Rapidly generating 2D images and 3D models based on user prompts allows for fast iteration and experimentation without any specialized skills. Instructions can be generated from a 3D model automatically for one or more manufacturing machines or devices. The instructions can be transmitted to the manufacturing devices to initiate product production. Here again, skill and knowledge of the instruction sets of each manufacturing device are not needed.

Further, simulation capabilities and machine learning models can be utilized to validate a design against a range of physical, technical, and logistical constraints to ensure structural integrity, material compatibility, and production feasibility of a final product. By automating validation, product development time and resources are reduced while also minimizing the risk of errors and failures. User feedback, and success or failure of manufacturing, provide information to improve the machine learning models and simulations of the present disclosure, allowing continuous and seamless improvement in performance. Furthermore, federated learning techniques can be employed to enable continuous improvement of performance and adaptation to changing requirements, allowing the creation of complex products with increased efficiency and reduced costs.

### Example Implementation of Food Manufacturing

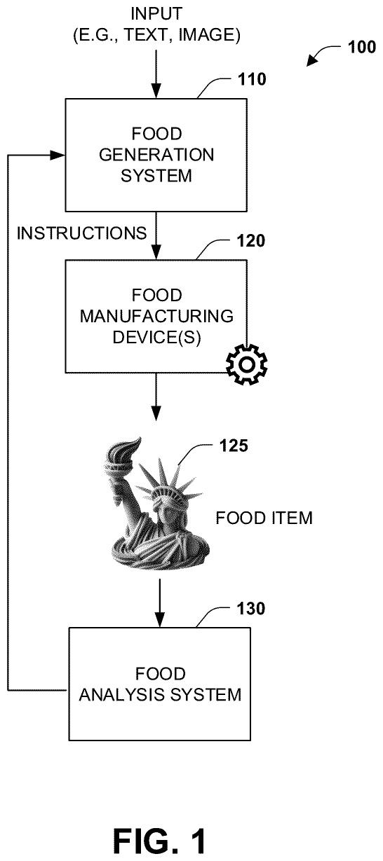

FIG. 1 depicts an example implementation of food manufacturing system 100, which automates the production of customized food products. The example implementation of food manufacturing system 100 includes food generation system 110, food manufacturing device(s) 120, food item 125, and food analysis system 130.

The food generation system 110 receives user prompts or design requests for specific food items and outputs manufacturing processing instructions. A user prompt can include a text-based description, one or more visual references, or both. A textual description of a desired food item can include the type of item, flavor profile, design element, or special requirements. For example, a text prompt could be, “Generate a dessert made of mint gelato in the shape of the Statue of Liberty with a torch flame made out of raspberry sorbet.” The user could also provide reference images of the Statue of Liberty as well as example gelato sculptures to aid in the generation of a desired food product. Using the text-based description and visual references, the food generation system 110 can generate one or more images of the food product and, subsequently, a three-dimensional model of the food product based on the one or more images of the food product, for instance by utilizing one or more generative models. Next, manufacturing instructions can be generated utilizing the 3D model. For example, instructions for the Statue of Liberty dessert can be generated for a 3D food printer. The instructions could include extruding a base layer of gelato with a diameter of 4 inches and a height of 1 inch, a robe-shaped layer on top of the base layer with a height of 4 inches, a head layer of 1 inch, and a torch layer with a flame made of raspberry sorbet. Further instructions could indicate that the gelato layers should be partially frozen between each extrusion step to maintain the structural integrity of the dessert. In other words, the output from the food generation system 110 serves as instructions for downstream food manufacturing devices to produce a customized food product.

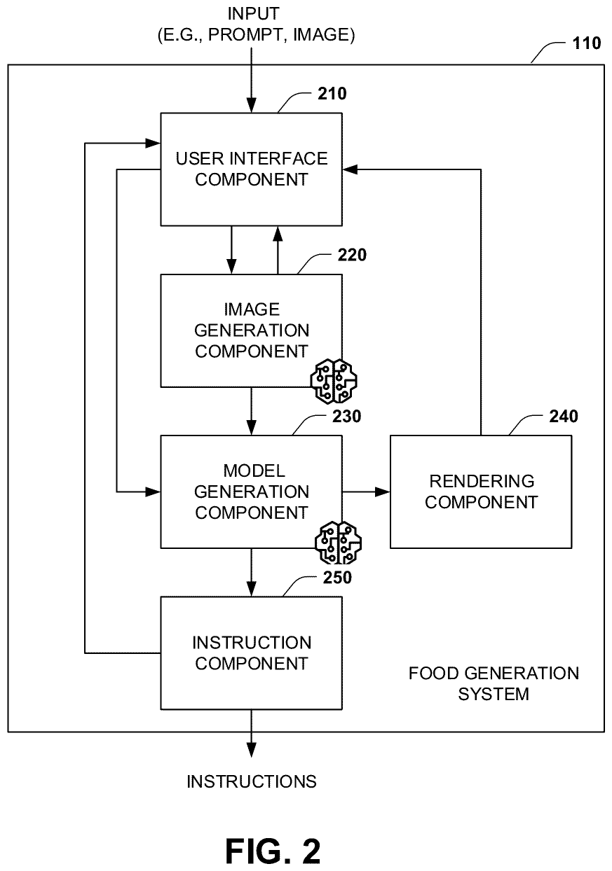

Turning to FIG. 2, an example food generation system 110 is illustrated in further detail. The food generation system 110 includes a user interface component 210, image generation component 220, model generation component 230, rendering component 240, and instruction component 250.

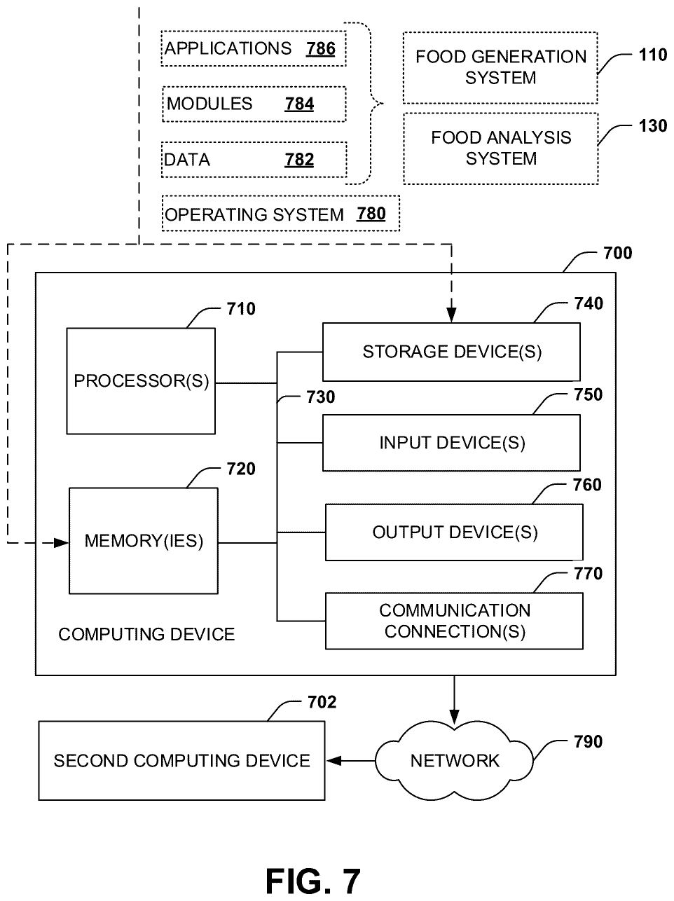

The user interface component 210, image generation component 220, model generation component 230, rendering component 240, and instruction component 250 can be implemented by at least one processor (e.g., processor(s) 710 of FIG. 7) coupled to at least one memory (e.g., memory 720 of FIG. 7) that stores instructions that cause the at least one processor to perform the functionality of each component when executed. Consequently, a computing device can be configured to be a special-purpose device or appliance that implements the functionality of the food generation system 110. Further, each component can implement or employ a machine-learning model, including a generative AI model, to supplement or perform the functionality of the component. Furthermore, all or portions of the food generation system 110 can be distributed across computing devices or accessible through a network service. For instance, the food generation system 110 can be implemented online as a subscription-based software as a service (SaaS) and need not be directly attached to food manufacturing devices 120.

The user interface component 210 is operable to allow users to submit prompts and interact with the food generation system 110. The user interface component 210 can receive text-based prompts describing a food item that they would like created. For example, the user interface can present an input text box on a computing device display to accept textual prompts. The user interface component 210 can also support uploading reference images or sketches to provide visual guidance to the food generation system 110. For example, a user can employ a generative model to produce an image from text, download a free-to-use image from the web, or sketch the image. The user interface component 210 can employ natural language processing and computer vision techniques to interpret user prompts and translate them into a format suitable for further processing. For example, computer vision techniques can be utilized to produce text that describes the image, which can be subject to further processing alone or in combination with a textual description. Further, the user interface component 210 can be operable to display images and models of food products before they are manufactured and enable interactions with visual representations to provide feedback to refine designs. In one embodiment, the user interface component 210 can enable verbal interaction and can employ voice-to-text technology to produce a corresponding text prompt.

The image generation component 220 is operable to generate a visual representation of a food product based on a user's textual and visual prompt. In accordance with one embodiment, the image generation component 220 implements or employs machine learning and computer vision techniques to translate the user's description and references into a two-dimensional rendering of desired food items. Generative models, such as generative adversarial networks (GANs) or other deep learning models (e.g., convolutional neural networks (CNNs), stable diffusion models, and transformers), can be employed to produce images that depict the shape, texture, and appearance of a requested food item. In certain embodiments, the images can be generated from multiple angles through the user interface component 210. In certain embodiments, the image generation component 220 employs a generative model to produce photorealistic images of the desired food item. For example, if a user submits a prompt for a “Statue of Liberty Gelato” dessert, the image generation component 220 would first analyze the textual description and any reference images provided. It would then use a generative model trained on a large dataset of food imagery to generate one or more images that depict the requested dessert. The generated images can then be presented to the user through the user interface component 210, enabling them to review product images before further processing. In one embodiment, the image generation component 220 can produce a number of different images and present and request the selection of an image through the user interface component 210. In a situation in which a generated image includes more content than the desired food item (e.g., people, restaurant background), a segmentation model may be employed to separate an object from its background or remove undesirable object parts. A user can further edit a 2D image through additional instructions, editing tools, or starting again with a new prompt. The image generation capability allows users to collaborate on the design and visualization of their custom food creations before they are produced.

The model generation component 230 is operable to employ images produced by the image generation component 220 to create a 3D model of a food item. The model generation component 230 can utilize a combination of computer vision and 3D modeling technology to transform two-dimensional images into three-dimensional representations. In one instance, an off-the-shelf product can be utilized to generate a 3D model, such as Meshy™. For example, if the image generation component 220 produces a series of photorealistic images depicting a “Statue of Liberty Gelato” dessert, the model generation component 230 can analyze these images and extract spatial and structural information. The spatial and structural information can be used to produce a 3D mesh model of the dessert with dimensions, shapes, and material properties. The model generation component 230 can employ various techniques to build a 3D model from 2D images including depth estimation and surface reconstruction. For example, if the images produced represent multiple views or angles of the food item, the model generation component 230 can employ stereo vision technology to analyze the differences between the images and infer the depth and three-dimensional structure of the food item. The model generation component 230 can employ other techniques or technologies if only a single image is provided, such as monocular depth estimation, and exploit other information to produce a 3D model. The information can include shading, shadows, and surface texture, as well as user-provided information regarding the size, scale, and dimensions of a food item.

Once the 3D model is generated, the rendering component 240 can render one or more images associated with the model for presentation to a user through the user interface component 210. In one instance, the user interface component 210 can support 3D model viewing and optionally editing functionality, in which case the rendering component 240 can pass the model or a version thereof to the user interface component 210, or the rendering component 240 can be removed. Further, in accordance with one embodiment, off-the-shelf products such as Blender™ or Maya™ can be utilized to render the 3D model. In any event, a user is provided an opportunity to review and make changes associated with the model to further refine the food item prior to further processing. For example, a user could adjust the dimensions to increase or decrease the overall height of a gelato dessert or change the proportions of the base robe, head, and torch elements. Further, the user could change coloring or flavoring or add decorative elements such as sprinkles or other edible embellishments to customize the appearance of a gelato dessert. Similar to the image generation stage, the user can collaborate on the design of the custom food item to meet their specifications and preferences.

The instruction component 250 is operable to receive a 3D model produced by the model generation component 230 and generate instructions regarding how to produce the custom food item in accordance with the model. For example, the instruction component can generate a set of machine-readable instructions or commands that can be executed by 3D printing and assembly equipment from a 3D model. The instruction component 250 can also determine an appropriate sequence and parameters for extruding different gelato layers, such as extrusion rate, layer heights, and temperatures. The instruction component 250 can also analyze the process and materials in view of various constraints and interact with the user through the user interface component 210 to identify issues and optionally make recommendations as described further below.

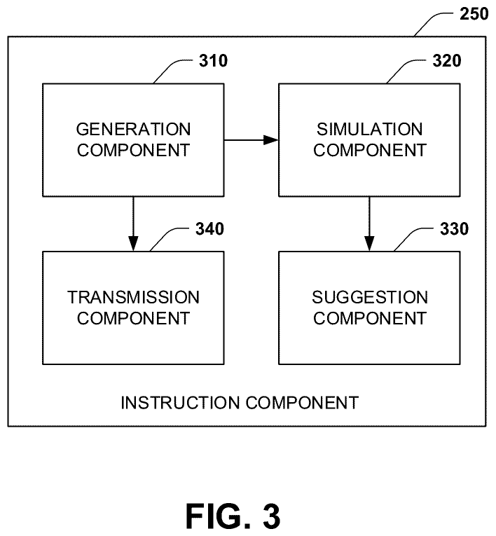

Turning to FIG. 3, an example instruction component 250 is illustrated in further detail. As shown, the instruction component 250 includes generation component 310, simulation component 320, suggestion component 330, and transmission component 340, which are subcomponents of instruction component 250.

The generation component 310 is operable to generate instructions to control food manufacturing devices. More specifically, the generation component 310 produces machine-readable instructions, code, or commands that are executable by food production equipment such as 3D printers, CNC machines, robotic arms, and ovens, among other things. The instructions can specify an optimal sequence of operations, such as an order of ingredient extrusion, assembly, and any post-processing steps like cooling or decoration. In accordance with one embodiment, the instructions can be transmitted to the appropriate equipment. More specifically, the transmission component 340 transmits the instructions to the appropriate food production equipment, and ensures (where such functionality is supported) that the food production equipment is functional and the instructions has been received successfully.

The simulation component 320 is operable to execute a simulation of the instructions and production of the food item. The simulation component 320 can receive instructions produced by the generation component 310 and simulates various steps of a manufacturing workflow including 3D printing of layers of material, material characteristics, temperature profiles, cooling requirements, and the coordination of different production devices. In one instance, off-the-shelf products can be employed to perform a simulation such as NVIDIA Modulus™, Omniverse™, or Isaac Sim™. The simulations component 320 seeks to identify potential issues or areas for improvement before production begins. In one instance, the simulation component 320 can determine the structural integrity of a food item. In other words, a determination can be made as to whether a food item is likely to collapse under its own weight or be unstable when moved. In another instance, the simulation component 320 can identify potential interference or collisions between manufacturing devices. In yet another instance, the simulation component 320 can detect material waste and issues affecting production speed. In terms of the ongoing gelato dessert example, the simulation component 320 can determine whether the gelato is stable or likely to collapse, and temperature and cooling requirements can be simulated to determine whether the gelato maintains a desired texture and consistency. The results of the simulation can be returned to a user through the user interface component 210 to potentially make adjustments.

The suggestion component 330 is operable to generate and provide suggestions to a user regarding a food item to be produced. In accordance with one embodiment, the suggestion component can receive simulation results from the simulation component 320 and determine or infer a corrective action for any issues. For example, simulation results can identify potential problems such as structural integrity concerns, material waste, or inefficient production times. The suggestion component 330 can generate one or more recommendations to improve the food product, the instructions that produce the food product, or both. For example, changes to the 3D model may be recommended to improve structural integrity. For instance, beam thickness adjustments may be recommended for a chocolate sculpture of the Eiffel Tower to prevent it from collapsing. Other suggestions can include adjustments to parameters such as extrusion speeds, temperatures, or layer heights to enhance the quality and consistency of the food product. Further, recommendations can be made based on constraints, including material availability and manufacturing equipment capabilities.

In accordance with one embodiment, the suggestion component 330 can implement or employ heuristic rules, machine learning models, or both to analyze simulation data and generate targeted recommendations. Heuristic rules can be based on established principles, best practices, and domain expertise and provide a framework for identifying issues and generating appropriate recommendations. For example, a rule might indicate that if simulation data indicates that gelato layers are at risk of structural failure, a recommendation is to adjust the extrusion speed or layer height to improve the structural integrity. A machine learning model can be trained on a large set of previous simulation data and successful actions and employed to identify more complex patterns and relationships within simulation data than heuristic rules. For example, a machine learning model may determine an optimal temperature for a gelato extrusion process based on patterns in simulation data. Heuristic rules and machine learning models enable the suggestion component to generate a comprehensive set of recommendations to improve the food item as well as the manufacturing instructions to ensure the successful production of the food item.

In accordance with another embodiment, the suggestion component 330 can further provide recommendations to improve the taste, calories, or other characteristics associated with a food product. Again, heuristic rules, machine learning models, or both can be employed to analyze a food item and make recommendations or suggestions to improve the food item. For example, a heuristic rule might state that if sugar content is higher than a threshold percentage of the food item as a whole, then it is too sweet and recommend a reduction of the amount of sugar. Further, a machine learning model can infer poor taste based on a combination of food materials that most people do not like and recommend a different material or combination of materials to improve the taste.

Returning to FIG. 1, the food generation system 110 provides instructions to one or more food manufacturing devices 120. Food manufacturing devices refer to equipment and machinery utilized to produce food products. Examples of food manufacturing devices 120 can include 3D food printers, CNC machines, lathes, robotic assembler arms, ovens, freezers, mixers, dispensers, and packaging machines, among others. Food manufacturing devices can be programmed to work together to produce custom food items envisioned by users.

The one or more food manufacturing devices 120 produce a food item or product. As shown, the food item 125 is a mint gelato Statue of Liberty with a raspberry torch fire in accordance with the continuing example herein. Of course, this is merely one example of a potentially infinite number of possible food items that can be produced by the food manufacturing devices 120. Furthermore, non-food items can also form part of a food item or product, such as packaging, tableware, and utensils, among other things. Such non-food items may be added, modified, or removed before, during, or after manufacture, or manufactured along with the food item, as instructed.

The food analysis system 130 is operable to analyze the food item 125 after it has been manufactured to determine if it meets specifications and a desired quality. In accordance with one embodiment, the food analysis system 130 can utilize a variety of sensors to monitor the properties of the produced food item 125. For instance, cameras can be employed to capture the visual properties of the food item. The image data can be analyzed utilizing computer vision and image processing techniques. The analysis can focus on detecting and evaluating the shape, color, and surface details of a food item 125 and comparing them with the original design specifications (e.g., prompt, images, 3D model). The results of the food analysis system 130 can be provided to the food generation system 110 to enable corrections to be made to generate a desired food item 125.

For example, high-resolution cameras can capture the gelato Statue of Liberty food item 125 from multiple angles. Computer vision technology can analyze the visual images to evaluate the accuracy of the gelato food item's shape, dimensions, and color compared to the corresponding 3D model. The food analysis system 130 can also assess factors such as the smoothness of gelato layers, as well as definition and details regarding the crown and torch, for example. The food analysis system 130 can further compare measured properties of the food item, such as overall height and proportions of different features against specified requirements from the 3D model and flag any deviations. Any deviations or defects can be provided back to the food generation system 110 to adjust the manufacturing process in terms of the instructions and, potentially the simulation.

In accordance with one embodiment, the food generation system 110 can incorporate federated learning to enable continuous improvement of performance. Federated learning enables the food generation system 110 to learn from the collective experiences of multiple users without sacrificing user privacy associated with underlying data. When users interact with the food generation system 110 and provide feedback or make adjustments to generated food products, that information can be captured and used to update machine learning models associated with a local instance of the system. Localized model updates can then be shared with a central federated learning server, which can aggregate changes from multiple users without accessing their private data. The federated learning server can then analyze the aggregated model updates to identify patterns and insights that can improve the overall performance of the food generation system 110, for example, through improved machine parameter settings (e.g., 3D printer) and more accurate simulations. The updated global model can then be shared with local instances, allowing the system to continuously learn and adapt, which enhances the quality, efficiency, and customization capabilities of the food generation system 110.

The food generation system 110 provides a streamlined and automated approach to food item development by transforming a user's initial prompt into a realized food item, which reduces the time and resources required for conventional manual design and prototype workflows. The food generation system 110 also provides increased manufacturing precision and consistency by generating manufacturing instructions from a 3D model. Furthermore, the food generation system provides for improved design visualization and collaboration by generating 2D images and 3D models based on a user's prompt. The images and models allow a user to preview and provide feedback on the food item before it is produced.

The food analysis system 130 provides automated quality assurance and control as well as continuous improvement and optimization of a manufacturing process through feedback. Furthermore, the ability to detect and address issues with a final food product reduces waste and increases efficiency.

### Example Food Generation Methods

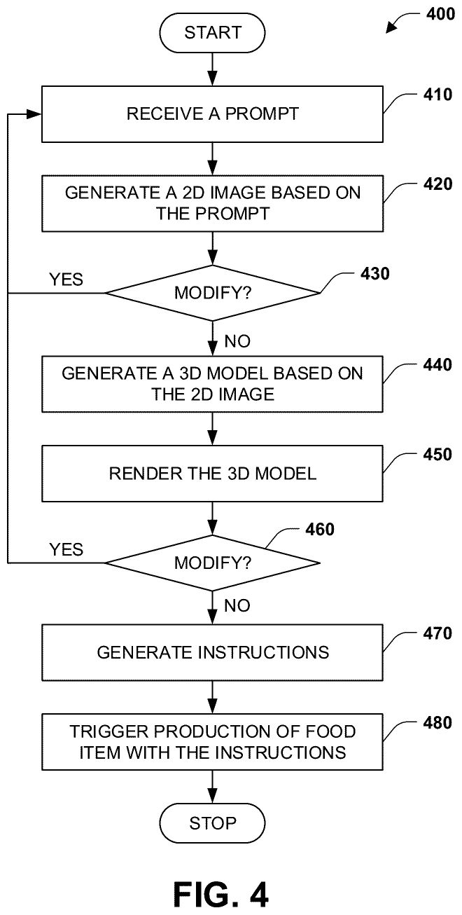

FIG. 4 depicts an example method 400 of food generation. In one aspect, method 400 can be implemented by the food generation system 110 of FIGS. 1, 2 and 7.

The method 400 starts at block 410 by receiving a prompt. A prompt refers to an initial request or description provided by a user for a food item the user would like to produce. The prompt can be received through a user interface, such as user interface component 210 of FIG. 2. The prompt can be a text prompt, a visual prompt, or both in accordance with certain embodiments. A text prompt describes a food item with a textual description. A visual prompt such as an image provides visual guidance for food generation.

The method 400 proceeds to block 420 by generating one or more 2D images of a food item based on the prompt. In accordance with one aspect, a generative model, or more specifically, an image generative model (e.g., DALL-E, CLIP), can be employed to convert a prompt into one or more images. Image generative models can employ advanced algorithms and use deep learning techniques to create realistic images through a fusion of artificial intelligence, computer vision, and natural language processing.

The method 400 continues to block 420, with determining whether the generated images are to be modified. In one instance, the user can be presented with the generated images and provided the opportunity to modify the images prior to further processing. If the one or more generated images are to be modified (“YES”), the method 400 continues at block 420, where new images are generated, for example, based on a modified prompt. Alternatively, image processing software can be used to modify an image directly. If the one or more images are not to be modified (“NO”), the method 400 continues at block 440.

The method 400 proceeds at block 440, with generating a 3D model based on the one or more 2D images. A combination of computer vision techniques and 3D modeling software can be employed to transform 2D images into 3D representations. For example, if images of multiple angles of a food item are available, stereo vision algorithms can analyze the difference between the images and infer the depth and 3D structure of a food item to aid in generating a 3D model.

The method 400 continues at block 450 with rendering the 3D model. Rendering the 3D model can involve generating a visual representation of the 3D model. A visual representation can be an image of the food item as represented by the 3D model. This allows a user to preview a food item represented by the model in a user interface and can permit adjustments or changes to refine the 3D model.

The method 400 continues at block 460 with determining whether a modification is desired. An image of a food item displayed to a user in a user interface can reveal an issue or detail that may have been overlooked and needs to be addressed. If a modification is to be performed (“YES”), the method 400 continues back to 410, where a new prompt is provided. In accordance with one embodiment, context can be provided with the new prompt. For instance, the previous prompt can provide context for the new prompt. In accordance with one aspect, a rendered image of the 3D model can be provided alone or in combination with text describing what is to be generated. If a modification is not to be performed (“NO”), the method continues at block 470.

The method 400 continues at block 470 with generating instructions. The instructions can correspond to computer-executable code, commands, or the like that control manufacturing equipment. In accordance with one embodiment, the 3D model can be sliced into a series of horizontal layers that can be sequentially produced by manufacturing equipment, such as a 3D food printer. Based on the sliced layers, specific tooling paths and movements can be determined to reproduce the 3D model. Additionally, or alternatively, a generative model can be employed to generate instructions based on the 3D model.

The method 400 next continues at block 480 with triggering the production of a food item with the instructions. In one instance, a sequence of instructions can be provided to a 3D printer and executed by the 3D printer to produce the food item.

The method 400 provides a streamlined and automated approach to food item development by transforming a user's initial prompt into a realized food item, which reduces the time and resources required for conventional manual design and prototype workflows. The method 400 also provides increased manufacturing precision and consistency by generating manufacturing instructions from a 3D model. Furthermore, the method 400 provides for improved design visualization and collaboration by generating 2D images and 3D models based on a user's prompt. The images and models allow a user to preview and provide feedback on the food item before it is produced.

Note that FIG. 4 is just one example of a method, and other methods including fewer, additional, or alternative steps are possible consistent with this disclosure.

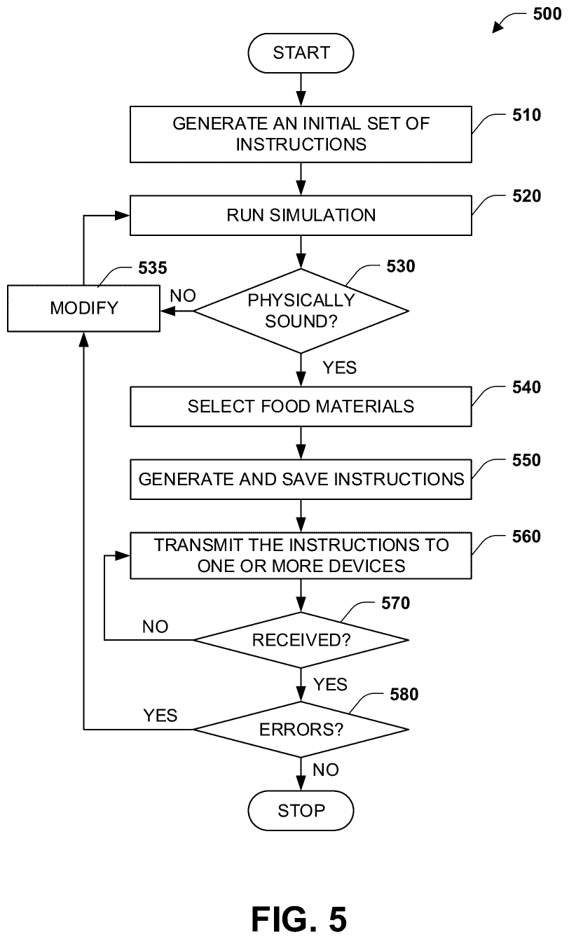

FIG. 5 is a flow chart diagram of method 500 of generating instructions. In one aspect, the method 500 can be implemented by the instruction component 250 of FIGS. 2 and 3.

The method 500 starts at block 510 with generating an initial set of instructions. The initial set of instructions can be generated from a 3D model.

The method 500 continues at block 510 with running a simulation. The initial set of instructions can be examined by simulating the production of a food item by executing the instructions. In one instance, the simulation can reveal the structural integrity of the food item. In this instance, structural integrity refers to the ability of the food item to maintain its intended shape, form, and structural stability. For example, a food item lacks structural integrity if it collapses under its own weight during the manufacturing process or prior to consumption.

The method continues at block 530 with determining whether a food item is physically sound based on the results of the simulation. If the food item is not physically sound (“NO”), the method 500 continues at block 535. If the food item is physically sound (“YES”), the method 500 continues at block 540.

At block 535, the method 500 continues with providing an opportunity to modify the food item design. For example, a user can be notified that the food item is not physically sound and provided an opportunity to modify the food item by way of a user interface.

The method 500 continues at block 540 with selecting food materials to be used in the manufacturing process. Selecting food materials can involve determining the particular properties of components like gelato needed to achieve a desired flavor, texture, and visual characteristics. Further, selecting food materials can involve selecting food materials effectively processed by manufacturing equipment, considering factors like shelf-life and caloric content, and optimizing material selection for factors like cost and availability. In accordance with one embodiment, an alert can be provided if particular food materials are unavailable. Warnings such as high cost or manufacturing time, dietary concerns, flavor or chemical incompatibility, among other things, may also be generated at this stage, to allow the user to modify their selections and prompts.

The method 500 next continues at block 550 with generating and saving instructions. The instructions include the processing instructions, which include identified food materials or ingredients.

Next, the method 500 proceeds to block 560 with transmitting the instructions to one or more manufacturing devices, such as 3D food printers, lathes, and CNC machinery.

The method 500 continues at block 570 with determining whether the one or more manufacturing devices received the instructions. If the instructions were not received (“NO”), the method 500 loops back to block 560 to transmit the instructions again. If the instructions were received (“YES”), the method 500 continues to block 580. Time-out and error handling may also be implemented to facilitate operation and prevent hang-ups and infinite loops that prevent or delay continuation at block 580.

At block 580, the method 500 continues with determining whether and where any errors occurred. For example, an error can be received from a manufacturing machine due to improper instruction or unavailable food material, among other things. If there are errors (“YES”), the method 500 proceeds to block 535, where modifications can be made to address errors. If there are no errors (“NO”), the method 500 terminates.

Note that FIG. 5 is just one example of a method, and other methods including fewer, additional, or alternative steps are possible consistent with this disclosure.

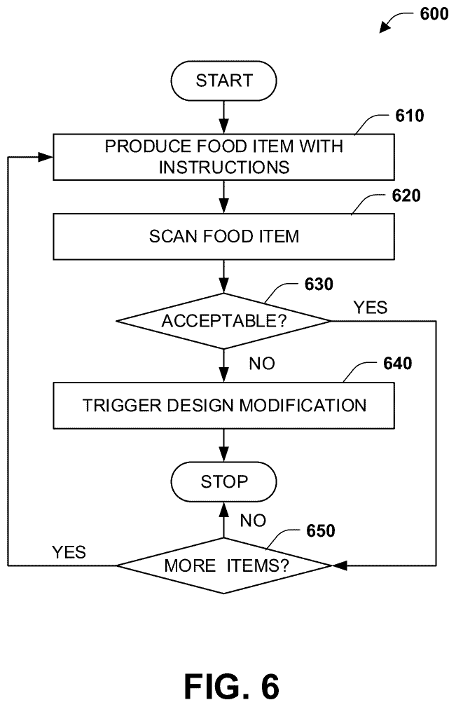

FIG. 6 is a flow chart diagram of a method 600 of food analysis. In accordance with one aspect, the method 600 can be implemented or executed by the food analysis system 130 of FIGS. 1 and 7.

The method 600 starts at block 610 with producing a food item with manufacturing equipment executing instructions provided by a food generation system 110 of FIG. 1. A single manufacturing device, such as a 3D food printer, or a combination of manufacturing devices can produce the food item.

The method 600 continues at block 620 with scanning a food item. In other words, one or more images of the food item can be captured. In one instance, the images can be captured at different angles and under different lighting conditions. In accordance with one aspect, high-resolution digital cameras can be utilized to obtain clear, close-up image of a food item surface and features. Further, specialized cameras can be utilized such as a depth sensing or 3D scanning camera can capture the three-dimensional shape and structure of a food item. Infrared cameras may also be utilized, for example, to provide information about heat signatures within a food product that can be helpful in evaluating proper cooking or cooling of a food time as well as any hot or cold spots.

The method 600 continues at block 630 with determining whether or not the food item is acceptable. The determination can be based on a comparison between the one or more images of the food item and an associated 3D model utilized as a basis for instructions to generate the food item. If the food item is unacceptable (“NO”), the method 600 continues at block 640. If the food item is acceptable (“YES”), the method 600 continues at block 650.

The method 600 continues at block 640 with triggering design modification. For example, a user can be notified of an issue with the food item in a food generation interface and can utilize the interface to modify the food item by updating a prompt, editing a 3D model, or changing the instructions, for example. Subsequently, the method 600 can terminate and restart again after modifications are complete.

The method 600 continues at block 650, with deciding whether or not to produce more food items. If no additional food items are to be produced (“NO”), the method 600 can terminate. If additional food items are to be produced, the method 600 returns back to block 610.

The method 600 provides several advantages. First, quality control and consistency are improved by scanning the item and comparing it to the desired items, which can aid in identifying defects or deviations. Further, looping between scanning the food item and updating a design or instructions allows for continuous improvement over time, which can lead to increased efficiency and reduced waste, among other things.

### Example Deployments

Some implementations of the embodiments of the food generation system 110 and the food analysis system 130 described herein can be deployed at malls, mass transit stations, stadiums, or other locations, for example, as a make-me-anything vending machine. Some implementations of the embodiments described herein may be used to make custom foods for catering or special events. Further, some implementations of the embodiments described herein may be used as rapid prototyping tools as part of product development efforts for further mass production or productization. Foods or food ingredients of varying physical properties (density, viscosity, elastic moduli, melting point), such as meringue, ice, ice cream, gel, foam, gelling, or binding agents, may be incorporated in the recipes and designs to achieve the desired combinations of taste, texture, and structural integrity. Generally, the food items produced by the embodiments described herein can be scaled as large or as small as desired based on the type of food production devices implemented in a given embodiment.

Some implementations of the embodiments described herein may produce food and serveware or tableware incorporating a theme, brand, logo, name, or trademark, for example, at a sales, marketing, or commemorative event.

Some implementations of the embodiments described herein may be used for product placement.

Some implementations of the embodiments described herein may be used to manufacture props for theater, cinema, parties, celebrations, and holidays (e.g., Halloween, Dia de los Muertos, Obon).

The prompts, 2D images, 3D models, recipes, manufacturing instruction sets, storage and serving suggestions, user feedback, improvement suggestions, manufactured items with or without customization, or any combinations thereof, may be bought, sold, exchanged, traded, aggregated, and so on, utilizing pre-existing (e.g. eBay, Amazon, Temu) or new marketplaces. Portable or stationary implementations of the subject disclosure may provide access to such marketplaces for pay, for free, for promotions or discounts, for in-app currency or tokens, etc., in single or multiple tiers of subscription, service, and so on.

Portable or stationary implementations of the subject disclosure can be of exceptional value and utility, inter alia, in locations where access to fast-food or ready-to-eat items is impossible or restricted. In some embodiments, significant utility may lie not in the manufactured item's appearance or taste, but in the manufacturing speed and item nutritional content, for example, incorporating necessary nutritional and medical ingredients. In some implementations, the hardware and/or software may be optimized to utilize any available raw food materials to provide quick and accessible nutrition, for instance, in disaster zones, remote areas or outposts, or the like.

In some implementations, aspects of the subject disclosure may be integrated into broader platforms, networks, or services. For example, it may be integrated with a Resource Management software to monitor and update ingredient prices and availability, forecast demand, prioritize certain designs or ingredients, provide feedback on usage patterns and user preferences, and so on.

### Example Operating Environment for Food Generation and Analysis

To provide a context for the disclosed subject matter, FIG. 7, as well as the following discussion, are intended to provide a brief, general description of a suitable environment in which various aspects of the disclosed subject matter can be implemented. However, the suitable environment is solely an example and is not intended to suggest any limitation on the scope of use or functionality.

While the above-disclosed system and methods can be described in the general context of computer-executable instructions of a program that runs on one or more computers, those skilled in the art will recognize that aspects can also be implemented in combination with other program modules or the like. Generally, program modules include routines, programs, components, and data structures, among other things, which perform particular tasks, implement particular abstract data types, or both. Moreover, those skilled in the art will appreciate that the above systems and methods can be practiced with various computer system configurations, including single-processor, multi-processor, or multi-core processor computer systems, mini-computing devices, server computers, as well as personal computers, hand-held computing devices (e.g., personal digital assistant (PDA), smartphone, tablet, watch . . . ), microprocessor-based or programmable consumer or industrial electronics, and the like. Aspects can also be practiced in distributed computing environments where tasks are performed by remote processing devices linked through a communications network. However, some, if not all, aspects of the disclosed subject matter can be practiced on standalone computers. In a distributed computing environment, program modules can be located in one or both of local and remote memory devices.

With reference to FIG. 7, illustrated is an example computing device 700 (e.g., desktop, laptop, tablet, watch, server, hand-held, programmable consumer or industrial electronics, set-top box, game system, compute node). The computing device 700 includes one or more processor(s) 710, memory 720, system bus 730, storage device(s) 740, input device(s) 750, output device(s) 760, and communications connection(s) 770. The system bus 730 communicatively couples at least the above system constituents. However, the computing device 700, in its simplest form, can include one or more processors 710 coupled to memory 720, wherein the one or more processors 710 execute various computer-executable actions, instructions, and or components stored in the memory 720.

The processor(s) 710 can be implemented with a general-purpose processor, a digital signal processor (DSP), an application-specific integrated circuit (ASIC), a field-programmable gate array (FPGA), or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. The processor(s) 710 can also be implemented as a combination of computing devices, for example, a combination of a DSP and a microprocessor, a plurality of microprocessors, multi-core processors, one or more microprocessors in conjunction with a DSP core, or any other such configuration. In one embodiment, the processor(s) 710 can be a graphics processor unit (GPU) that performs calculations concerning digital image processing and computer graphics. In another embodiment, the processor(s) 710 can be a tensor processing unit (TPU) for machine learning processing.

The computing device 700 can include or otherwise interact with a variety of computer-readable media to facilitate control of the computing device to implement one or more aspects of the disclosed subject matter. Computer-readable media can be any available media accessible to the computing device 700, including volatile and nonvolatile media and removable and non-removable media. Computer-readable media can comprise two distinct and mutually exclusive types: storage media and communication media.

Storage media includes volatile and nonvolatile, removable, and non-removable media implemented in any method or technology to store information, such as computer-readable instructions, data structures, program modules, or other data. Storage media includes storage devices such as memory devices (e.g., random access memory (RAM), read-only memory (ROM), electrically erasable programmable read-only memory (EEPROM)), magnetic storage devices (e.g., hard disk, floppy disk, cassettes, tape), optical disks (e.g., compact disk (CD), digital versatile disk (DVD) . . . ), and solid-state devices (e.g., solid-state drive (SSD), flash memory drive (e.g., card, stick, key drive)), or any other like mediums that store, as opposed to transmit or communicate, the desired information accessible by the computing device 700. Accordingly, storage media excludes modulated data signals as well as that which is described with respect to communication media.

Communication media embodies computer-readable instructions, data structures, program modules, or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, radio frequency (RF), infrared, and other wireless media.

Memory 720 and storage device(s) 740 are examples of computer-readable storage media. Depending on the configuration and type of computing device, the memory 720 can be volatile (e.g., random access memory (RAM)), nonvolatile (e.g., read-only memory (ROM), flash memory . . . ), or some combination of the two. By way of example, the basic input/output system (BIOS), including basic routines to transfer information between elements within the computing device 700, such as during start-up, can be stored in nonvolatile memory, while volatile memory can act as external cache memory to facilitate processing by the processor(s) 710, among other things.

The storage device(s) 740 include removable/non-removable, volatile/nonvolatile storage media for storing vast amounts of data relative to the memory 720. For example, storage device(s) 740 include, but are not limited to, one or more devices such as a magnetic or optical disk drive, floppy disk drive, flash memory, solid-state drive, or memory stick.

Memory 720 and storage device(s) 740 can include, or have stored therein, operating system 780, one or more applications 786, one or more program modules 784, and data 782. The operating system 780 acts to control and allocate resources of the computing device 700. Applications 786 include one or both of system and application software and can exploit management of resources by the operating system 780 through program modules 784 and data 782 stored in the memory 720 and/or storage device(s) 740 to perform one or more actions. Accordingly, applications 786 can turn a general-purpose computing device 700 into a specialized machine according to the logic provided.

All or portions of the disclosed subject matter can be implemented using standard programming and/or engineering techniques to produce software, firmware, hardware, or any combination thereof to control the computing device 700 to realize the disclosed functionality. By way of example and not limitation, all or portions of the food generation system 110 and food analysis system 130 can be, or form part of, the application 786 and include one or more program modules 784 and data 782 stored in memory and/or storage device(s) 740 whose functionality can be realized when executed by one or more processor(s) 710.

The input device(s) 750 and output device(s) 760 can be communicatively coupled to the computing device 700. By way of example, the input device(s) 750 can include a pointing device (e.g., mouse, trackball, stylus, pen, touchpad), keyboard, joystick, microphone, voice user interface system, camera, and motion sensor, among other things. The output device(s) 760, by way of example, can correspond to a display device (e.g., liquid crystal display (LCD), light emitting diode (LED), plasma, organic light-emitting diode display (OLED) . . . ), speakers, voice user interface system, printer, and vibration motor, among other things. The input device(s) 750 and output device(s) 760 can be connected to the computing device 700 by way of a wired connection (e.g., bus), wireless connection (e.g., Wi-Fi, Bluetooth), or a combination thereof.

The computing device 700 can also include communication connection(s) 770 to enable communication with at least a second computing device 702 utilizing a network 790. The communication connection(s) 770 can include wired or wireless communication mechanisms to support network communication. The network 790 can correspond to a personal area network (PAN), local area network (LAN), or a wide area network (WAN) such as the Internet. In one instance, the computing device 700 can correspond to a first computing device executing the food generation system 110. The second computing device 702 can correspond to a manufacturing machine, computer, controller, or the like associated with producing a food item.

Note that FIG. 7 is just one example of an operating environment consistent with aspects described herein, and other processing systems having additional, alternative, or fewer components are possible consistent with this disclosure.

### Example Clauses

Implementation examples are described in the following numbered clauses:

Clause 1: A method of food manufacturing, comprising receiving a prompt from a user, the prompt is text describing a food item to be produced, generating a two-dimensional image of the food item by a first generative artificial intelligence model based on the prompt, generating a three-dimensional model of the food item by a second generative artificial intelligence model based on the two-dimensional image, generating one or more instructions for producing the food item based on the three-dimensional model, and triggering production of the food item according to the one or more instructions.

Clause 2: The method of Clause 1, further comprising rendering the two-dimensional image of the food item, and receiving an updated prompt from the user in response to the two-dimensional image.

Clause 3: The method of Clauses 1-2 further comprising generating multiple two-dimensional images of the food item from different angles and generating the three-dimensional model of the food item based on the multiple two-dimensional images.

Clause 4: The method of Clauses 1-3, further comprising rendering the three-dimensional model and receiving an updated prompt from the user in response to the three-dimensional model.

Clause 5: The method of Clauses 1-4, further comprising generating a simulation of the food item and determining the food item is physically sound based on the simulation before generating the one or more instructions.

Clause 6: The method of Clauses 1-5, wherein triggering the production of the food item comprises transmitting the one or more instructions for execution by one or more additive or subtractive manufacturing devices.

Clause 7: The method of Clauses 1-6, wherein at least one of the manufacturing devices is a three-dimensional printer.

Clause 8: The method of Clauses 1-7, wherein at least one of the manufacturing devices is a computer numeric control lathe or mill.

Clause 9: The method of Clauses 1-8, further comprising scanning a produced food item, determining at least one difference between the produced food item and the three-dimensional model of the food item, and presenting an indication of the at least one difference.

Clause 10: A method, comprising scanning a food item produced by one or more additive or subtractive manufacturing devices based on one or more instructions automatically generated from a three-dimensional model produced in response to a prompt, determining a difference between the food item and the three-dimensional model, and transmitting the difference to a food generation system to trigger design modification.

Clause 11: A marketplace for the prompts, two-dimensional images, and three-dimensional models a food item, as well as for instructions for execution by one or more additive or subtractive manufacturing devices for manufacturing of the food item.

Clause 12: A processing system, comprising a memory comprising computer-executable instructions; and a processor configured to execute the computer-executable instructions and cause the processing system to perform a method in accordance with any one of Clauses 1-11.

Clause 13: A processing system, comprising means for performing a method in accordance with any one of Clauses 1-11.

Clause 14: A non-transitory computer-readable medium storing program code for causing a processing system to perform the steps of any one of Clauses 1-11.

Clause 15: A computer program product embodied on a computer-readable storage medium comprising code for performing a method in accordance with any one of Clauses 1-11.

### Additional Considerations

The preceding description is provided to enable any person skilled in the art to practice the various embodiments described herein. The examples discussed herein are not limiting of the scope, applicability, or embodiments set forth in the claims. Various modifications to these embodiments will be readily apparent to those skilled in the art, and the generic principles defined herein may be applied to other embodiments. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The methods disclosed herein comprise one or more steps or actions for achieving the methods. The method steps or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the embodiments shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public, regardless of whether such disclosure is explicitly recited in the claims.

What is claimed is:

1. A method of food manufacturing, comprising:
receiving a prompt from a user, the prompt is text describing a food item to be produced;
generating a two-dimensional image of the food item by a first generative artificial intelligence model based on the prompt;
generating a three-dimensional model of the food item by a second generative artificial intelligence model based on the two-dimensional image;
generating one or more instructions for producing the food item based on the three-dimensional model; and
triggering production of the food item according to the one or more instructions.

2. The method of claim 1, further comprising:
rendering the two-dimensional image of the food item; and
receiving an updated prompt from the user in response to the two-dimensional image.

3. The method of claim 1, further comprising:
generating multiple two-dimensional images of the food item from different angles; and
generating the three-dimensional model of the food item based on the multiple two-dimensional images.

4. The method of claim 1, further comprising:
rendering the three-dimensional model; and
receiving an updated prompt from the user in response to the three-dimensional model.

5. The method of claim 1, further comprising:
generating a simulation of the food item; and
determining the food item is physically sound based on the simulation before generating the one or more instructions.

6. The method of claim 1, wherein triggering the production of the food item comprises transmitting the one or more instructions for execution by one or more additive or subtractive manufacturing devices.

7. The method of claim 6, wherein at least one of the one or more additive or subtractive manufacturing devices is a three-dimensional printer.

8. The method of claim 6, wherein at least one of the one or more additive or subtractive manufacturing devices is a computer numeric control lathe or mill.

9. The method of claim 1, further comprising:
scanning a produced food item;
determining at least one difference between the produced food item and the three-dimensional model of the food item; and
presenting an indication of the at least one difference.

10. A system, comprising:
at least one processor; and
at least one memory that stores instructions that, when executed, cause the system to:
generate a two-dimensional image of a food item with a first generative artificial intelligence model based on a prompt from a user, wherein the prompt is text describing the food item to be produced;
generate a three-dimensional model of the food item with a second generative artificial intelligence model based on the two-dimensional image;
generate one or more instructions for producing the food item based on the three-dimensional model; and
trigger production of the food item according to the one or more instructions.

11. The system of claim 10, wherein the instructions further cause the system to:
render the two-dimensional image of the food item; and
receive an updated prompt from the user in response to the two-dimensional image.

12. The system of claim 10, wherein the instructions further cause the system to:
generate multiple two-dimensional images of the food item from different angles; and
generate the three-dimensional model of the food item based on the multiple two-dimensional images.

13. The system of claim 10, wherein the instructions further cause the system to:
render the three-dimensional model; and
receive an updated prompt from the user in response to the three-dimensional model.

14. The system of claim 10, wherein the instructions further cause the system to:
generate a simulation of the food item; and
determine the food item is physically sound based on the simulation before generating the one or more instructions.

15. The system of claim 10, wherein the instruction that triggers the production of the food item further causes the system to transmit the one or more instructions for execution by one or more additive or subtractive manufacturing devices.

16. The system of claim 15, wherein at least one of the one or more additive or subtractive manufacturing devices is a three-dimensional printer.

17. The system of claim 15, wherein at least one of the one or more additive or subtractive manufacturing devices is computer numeric control lathe or mill.

18. The system of claim 10, wherein the instructions further cause the system to:
scan a produced food item;
determine at least one difference between the produced food item and the three-dimensional model of the food item; and
present an indication of the at least one difference.

19. A method, comprising:
scanning a food item produced by one or more additive or subtractive manufacturing devices based on one or more instructions automatically generated from a three-dimensional model produced in response to a prompt;
determining a difference between the food item and the three-dimensional model; and
transmitting the difference to a food generation system to trigger design modification.

20. The method of claim 19, further comprising:
generating one or more updated instructions based on the three-dimensional model and the difference; and
triggering production of the food item according to the one or more updated instructions.
